(19) United States
(12) Patent Application Publication
(10) Pub. No.: US 2007/0023884 A1
(43) Pub. Date: Feb. 1, 2007

(54) Package

(75) Inventors: Per-Henrik Branzell, Karlstad (SE); Mats Fredlund, Karlstad (SE); Lars Sandberg, Hammaro (SE)

Correspondence Address: GREER, BURNS & CRAIN, 300 S WACKER DR, 25TH FLOOR, CHICAGO, IL, 60606, US

(73) Assignee: Stora Enso AB

(21) Appl. No.: 11/488,329

(22) Filed: Jul. 18, 2006

Related U.S. Application Data
(60) Provisional application No. 60/704,307, filed on Aug. 1, 2005.
(60) Provisional application No. 60/798,911, filed on May 9, 2006.

(51) Int. Cl. H01L 23/02

(52) U.S. Cl. 257/679

(57) ABSTRACT

The invention relates to a package, e.g. a blister package, comprising two spaced apart first and second walls formed and joined to each other to define a cavity between them, said walls having peripheral edges and being sealed together at a peripheral joint essentially along the edges wherein a portion of said peripheral joint comprises at least two conductive surfaces and an electrically weakable adhesive. The invention further relates to an apparatus for supplying electrical power to the package.

### FIELD OF THE INVENTION

The invention relates to a package, e.g. a blister package, comprising two spaced apart first and second walls formed and joined to each other to define a cavity between them, said walls having peripheral edges and being sealed together at a peripheral joint essentially along the edges

The invention further relates to an apparatus for supplying current to an electrically weakable adhesive and a method of closing and a method of opening a package.

### BACKGROUND

Packaging units for articles, also known as blister packages, are usually made from two plastic material walls or foils. These walls are relatively stiff synthetic sheets, with a heat seal weld along the major peripheral edges or surrounding the entire periphery. Blister packages are also known to have a plastic blister front and a cardboard rear wall, the plastic front being glued to the cardboard. Other known blister packages include a plastic blister front and a flat foil rear wall.

One disadvantage of these known blister packages is that they are frequently difficult to open, usually requiring scissors or considerable tearing force, which is inconvenient for the user.

To overcome this problem, the prior art blister packages usually include some kind of a tear-out part for the user to get access to the product.

However, these latter prior art packages are prone to theft and product tampering because the item contained therein can be effortlessly removed increasing opportunities for theft and tampering of the item.

It is well known in the art that polymer chains can be broken by the application of a voltage. This is for example discussed in a review article by G. S. Shapoval (Cathodic initiation of reactions of macromolecule formation and degradation, Theoretical and Experimental Chemistry, Volume 30, Number 6, November 1994).

U.S. Pat. No. 6,620,308 B2 discloses a material for use in the airplane industry. As is evident from the published patent, the material has been developed under the supervision of the U.S. Department of the Air Force. The material is developed for use as coatings and adhesives. It is further elaborated in U.S. Pat. No. 6,620,308 that the adhesive bonds and polymeric coatings are commonly used in the assembly and finishing of manufactured goods. It is stated that adhesive bonds are used in place of mechanical fasteners, such as screw, bolts and rivets, to provide bonds with reduced machining costs and greater adaptability in the manufacturing process. It is further discussed that adhesive bonds distribute stresses evenly, reduce the possibility of fatigue, and seal the-joints from corrosive species. It further asserts that, similarly, polymer-based coatings are commonly applied to the exterior surface of the manufactured products. These coatings provide protective layers that seal the surface from corrosive reactants, as well as provide a painted surface that can the aesthetically pleasing.

The composition disclosed in U.S. Pat. No. 6,620,308 B2 has a matrix functionality and an electrolyte functionality, wherein the electrolyte functionality is provided by a block copolymer or a graft copolymer. The matrix functionality provides an adhesive bond to a substrate, and the electrolyte functionality provides sufficient ionic conductivity to the composition to support a faradic reaction at an interface with an electrically conductive surface in contact with the composition, whereby the adhesive bond is weakened at the interface. The composition may be a phase-separated composition having first regions or substantially matrix functionality and second regions of substantially electrolyte functionality.

### SUMMARY OF THE INVENTION

One object of the present invention is to provide a blister package that is easily opened.

Another object of the present invention is to provide a blister package that renders unauthorized opening difficult.

A third object of the present invention is to provide a blister package that is easily opened and yet protected against theft or unauthorized tamper.

These, as well as other advantages, has been achieved by a package comprising two spaced apart first and second walls formed and joined to each other to define a cavity between them, said walls having peripheral edges and being sealed together at a peripheral joint essentially along the edges which package is characterized in that a portion of said peripheral joint comprises at least two conductive surfaces and an electrically weakable adhesive.

By providing a portion of the peripheral joint of a package, e.g. a blister package, with two conductive surfaces and an electrically weakable adhesive, it is possible to provide blister packages which are protected against theft and/or tampering, but yet easy to open.

Prior to the opening of the package, a voltage is applied to the electrically weakable adhesive by an external electrical power source. Thereby, the portion of the peripheral joint comprising the electrically weakable-adhesive can be opened. This initial opening of the package triggers or facilitates the opening of the rest of the peripheral joint whereby the user can easily get access to the article contained in the package. The need of an external electrical power source for the opening of the package prevents theft and/or tampering, since it makes it more difficult to an unauthorized user to get access to the article. The external electrical power source can, for example, be located at the cash register and the cashier can supply the electrical current to the package when the customer pays for the article.

The portion of the package provided with two conductive surfaces and an electrically weakable adhesive can be the whole peripheral joint, i.e. 100% of the peripheral joint. However, since the opening of a part of the peripheral joint triggers the rest of the opening it is in most cases not necessary that the whole peripheral joint is provided with the conductive surfaces and an electrically weakable adhesive. In a preferred embodiment, the portion of the package provided with two conductive surfaces and an electirically weakable adhesive only constitute a part of the peripheral joint, i.e. not the whole peripheral joint. The portion provided with two conductive surfaces and an electrically weakable adhesive can, for example, constitute less than 50% of the peripheral joint, preferably less than 25% of the peripheral joint. This saves materials and reduces the production cost.

The conductive surfaces can be formed by foils or, alternatively, of films comprising at least one conductive polymer. In a preferred embodiment, at least one of the walls forming the package comprises at least one conductive polymer, thus forming the conductive surface. In this way no extra conductive material needs to be added.

The “at least two conductive surfaces” can in a direction from the cavity to the peripheral joint at least partly extend past the first and second walls. This ensures access to the conductive surfaces whereby the application of a voltage to the electrically weakable adhesive is facilitated. In a preferred embodiment of the invention, the conductive surfaces are adapted to be swiped through a voltage supplying apparatus. The swiping movement improves the contact between the conductive surfaces of the package and the conductors on the flanges and thus improves the current supply to the conductive surfaces. Furthermore the friction between the conductors and the flanges scratches off potential impurities, such as potential oxide layers on the conductors, which improves the contact even further.

In another preferred embodiment of the invention, the first conductive surface is located on the first wall of the package and the second conductive surface is located on the second wall and the electrically weakable adhesive bridges the distance between the first and the second conductive surface. This facilitates the swiping of the conductive surfaces through the voltage supplying apparatus.

The invention may further be said to involve an apparatus for supplying current to the electrically weakable adhesive of the package described above, which apparatus comprises a first and a second flange forming a swipe slot and means for applying a voltage between said conductors.

Preferably, said conductors are separated in a direction perpendicular to the width of the swipe slot and preferably also perpendicular to the swiping movement. This assures that direct contact between the conductors is avoided and thus prevents shortcircuiting.

In a preferred embodiment of the present invention, the voltage supplying apparatus forms a part of a cash register system and the cashier or sales clerk swipes the package through the voltage supplying apparatus when the customer is paying for the product. This gives an even better protection against theft and/or tampering, since the package has to be swiped through the voltage supplying apparatus before it can be opened. The swiping movement is a well known working operation to the sales clerk, since a similar operation is performed today with credit cards.

The voltage supplying apparatus can further comprise at least one bar code reader. In this way, the user, e.g. a sales clerk, only has to swipe the package once. In another embodiment, the apparatus can further comprise at least one card reader. This reduces the number of components needed at the cash register system. The apparatus can comprise a bar code reader as well as a card reader. The bar code reader and/or card reader can, e.g., be located on the flanges.

The invention may also be said to involve a method comprising; providing two spaced apart first and second walls forming a cavity between them, said walls having peripheral edges, sealing said walls together at a peripheral joint essentially along the edges and providing a portion of said peripheral joint with at least two conductive surfaces and an electrically weakable adhesive.

It may also be defined as a method of providing a blister package with at least two conductive surfaces and an electrically weakable adhesive and swiping the part of said blister package comprising said two conductive surfaces through a voltage supplying apparatus.

### BRIEF DESCRIPTION OF THE DRAWINGS

The invention will by way of example be described in more detail with reference to the appended schematic drawings, which shows a presently preferred embodiment of the invention.

FIG. 1 shows a blister package comprising a basic structure.

FIG. 2 shows a cross section of the part of a blister package comprising a basic structure.

FIG. 3 illustrates a method of manufacture a blister package comprising a basic structure.

FIG. 4 shows an embodiment of a package wherein the separation of the walls after the breaking or weakening of the bonds in the electrically weakable adhesive is facilitated.

FIG. 5 shows another embodiment of a package wherein the separation of the walls after the breaking or weakening of the bonds in the electrically weakable adhesive is facilitated.

FIGS. 6 and 7 shows an apparatus for supplying voltage to the electrically weakable adhesive.

### DETAILED DESCRIPTION OF PREFERRED EMBODIMENTS

The packages described in the following make use of an electrically weakable adhesive material. The inventive packages are provided with two conductive surfaces acting as electron and/or ion emitter and receiver connected with a bonding layer, comprising the electrically weakable adhesive material. The bonding layer possesses adhesive properties and conductive properties. When a voltage is applied between the active surfaces and current flows through the bonding layer, bonds formed in or between the bonding layer and at least one of the conductive surfaces are broken or weakened. Thus, the bonding layer forms an electrically weakable adhesive.

The electrically weakable adhesive may bridge the complete distance between the active layers but may also be completed with additional layers of other materials capable of performing the necessary electrical and/or mechanical connection. Such materials may be conventional non electrically conductive adhesives, polymers, varnishes, or the like, or electrically conductive versions of respective material.

The electrically weakable material and different basic configurations of the conductive surfaces will initially be discussed in detail separately from the specific designs of the packages. The different designs of the packages will thereafter be discussed in detail. In some cases the design of the package will be discussed in combination with a specific kind of basic configuration. It should however be noted that this is for exemplifying purposes and that the different basic configurations may be combined with the different designs of the packages.

According to one embodiment the bonding layer is composed of a composition possessing both matrix functionality and electrolyte functionality. The matrix and the electrolyte functionalities may be formed by a single phase or several separate phases.

The matrix functionality provides the adhesive properties necessary to bind surfaces to one another mechanically or chemically. The matrix functionality may be provided by polymers, polymer resins or fibres that possess adhesive properties.

The electrolyte functionality provides the ion conductivity necessary to support a faradic reaction, i.e. an electrochemical reaction in which a material is oxidized or reduced, or some other chemical/physical reaction. The materials are preferably chosen and designed such that the reaction occurs at the interface between one or both of the active surfaces and the bonding layer. Alternatively the bonding layer may be designed such that the reaction will occur within the bonding layer. This may, e.g., be accomplished by providing islands of a material with electrolyte functionality within the matrix material. The electrolyte functionality may be provided by adding a salt to the material or by modifying the polymer so that it includes ion-coordinating moieties.

The electrically weakable adhesive used in the inventive packages may be the electrochemically disbondable composition ElectRelease™ supplied by EIC laboratories and disclosed in more detail in U.S. Pat. No. 6,620,308.

The inventive package comprises a basic structure, which basic structure comprises a first conductive surface and a second conductive surface being arranged at a distance from each other and an electrically weakable adhesive adapted to bridge the distance between the first and the second conductive surface. In a preferred embodiment, the first conductive surface is separated from the second conductive surface in a direction of a normal to the first surface, wherein the electrically weakable adhesive is bridging the distance between the first and second conductive surface. The electrical potential difference between the conductive surfaces is adapted to be provided by an external source of electrical energy. When a voltage is applied between the conductive surfaces current will flow between the conductive surfaces via the electrically weakable adhesive. This will cause the bonds in the electrically weakable adhesive or between the electrically weakable adhesive and one or both of the conductive surfaces to break or to weaken.

In one embodiment of the invention, the conductive surfaces are formed of foils. Alternatively, the conductive surfaces can be made of a film of conductive polymers. In a preferred embodiment, the walls forming the blister package can at least partly be made of a material comprising conductive polymers, whereby no extra conductive material needs to be added.

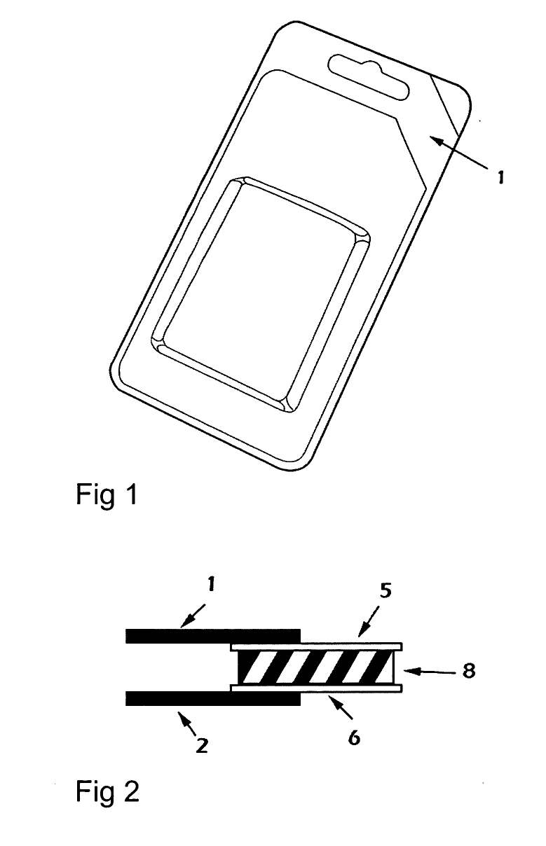

Referring to FIGS. 1 and 2, there is shown a packaging unit for articles, which packaging unit comprises the basic structure described above. The packaging unit comprises a first 1 and a second 2 spaced apart walls that have been formed to define a cavity 3 between them, commonly referred to as a blister. The article-receiving cavity or blister can be formed into one wall and the other can be flat, or, both walls can define parts of the article-receiving blister. Preferably, at least one of the walls is formed of plastic material, preferably transparent plastic. In one embodiment, both the upper and lower walls are made of plastic. Alternatively, one of the walls can be formed as a flat sheet of plastic, a flexible film or a fibrous material, such as cardboard, commonly referred to as a blister card.

The semi-rigid plastic material walls 1, 2 can be thermally formed from plastic materials, such as polyester materials. Suitably forming techniques include, but are not limited to, vacuum forming and deep drawing.

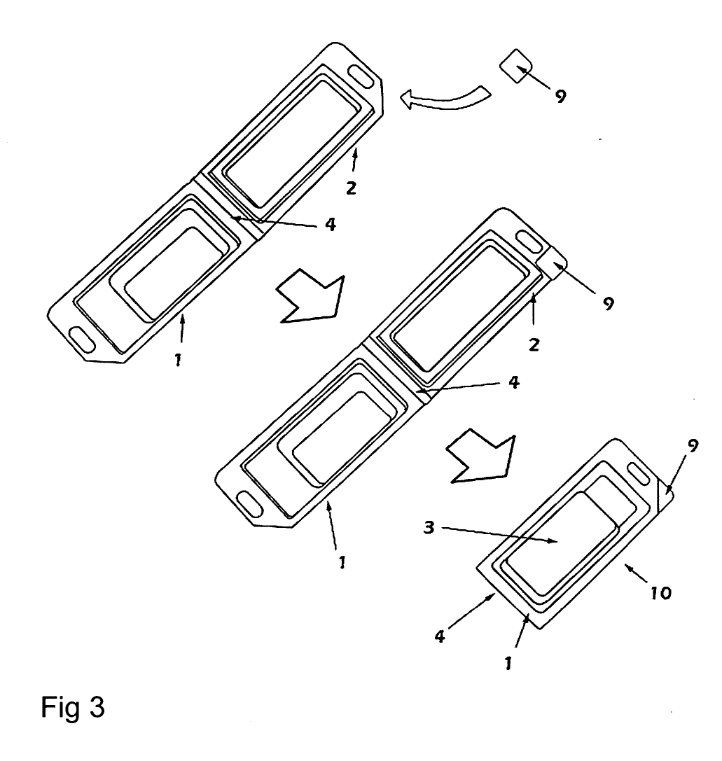

The packaging unit is sealed along the periphery. The joint can be achieved by use of any convenient technique such as adhesives, ultrasonic, heat sealing, radio-frequency (RF) sealing or firm mechanical interlock. The walls 1, 2 of the packaging unit 10 shown in FIG. 1 are formed of one sheet of material that has been creased and folded back on itself along one of the edges 4, which is further illustrated in FIG. 3. It is however also possible that the walls are formed of two separate pieces. A part of the peripheral joint comprises at least two conductive surfaces 5, 6 and an electrically weakable adhesive 8, i.e. a basic structure 9. Preferably, a first conductive surface, 5, is attached to the first wall, 1, and a second conductive surface, 6, is attached to the second wall 2 and the electrically weakable adhesive is applied between the first and second conductive surface 6, 7. The first and the second conductive surfaces 6, 7 extend outside the first and the second wall 1, 2 in a direction in the extension of the walls allowing the conductive surfaces to be accessible for an external electrical power source.

In the embodiment shown in FIG. 1, the basic structure comprising the conductive surfaces and the electrically weakable adhesive, is located in the peripheral joint at the approximate intersection of two adjacent side edges of the packing unit. However, the basic structure can be located anywhere in the peripheral joint of the packaging unit. In one preferred embodiment, the basic structure is located at one of the edges. This facilitates the swiping, since it in this way might be easier to control the swiping angle. Preferably, the basic structure extends on both sides of a corner of the packing unit. This facilitates the opening of the package after the swiping.

When a voltage is applied between the conductive surfaces, 5, 6, current will flow between the conductive surfaces via the electrically weakable adhesive. This will cause bonds in the electrically weakable adhesive or between the electrically weakable adhesive and one of the conductive surfaces to break or to weaken.

The voltage needed to break or weaken the bonds in the electrically weakable adhesive can be applied by an external power supply. In one embodiment, the voltage is supplied by the user swiping the part of the package comprising the basic structure through a swipe slot in a voltage supplying apparatus.

In a preferred manufacturing process, illustrated in FIG. 3, a basic structure 9 comprising a first and a second conductive surface and an electrically weakable adhesive is manufactured separately from the walls adapted to be sealed together and thereby form the cavity or blister. Prior to the sealing of the package along the periphery, said structure is arranged between the walls so that it covers a portion of the periphery and so at least the conductive surfaces extends a distance outside the walls. Thereafter, the package is sealed along the periphery using any convenient technique.

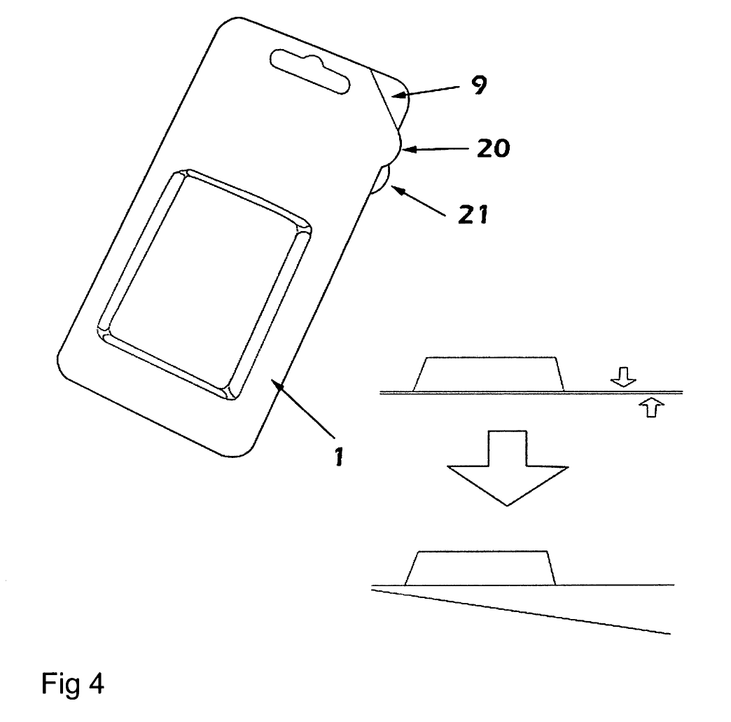

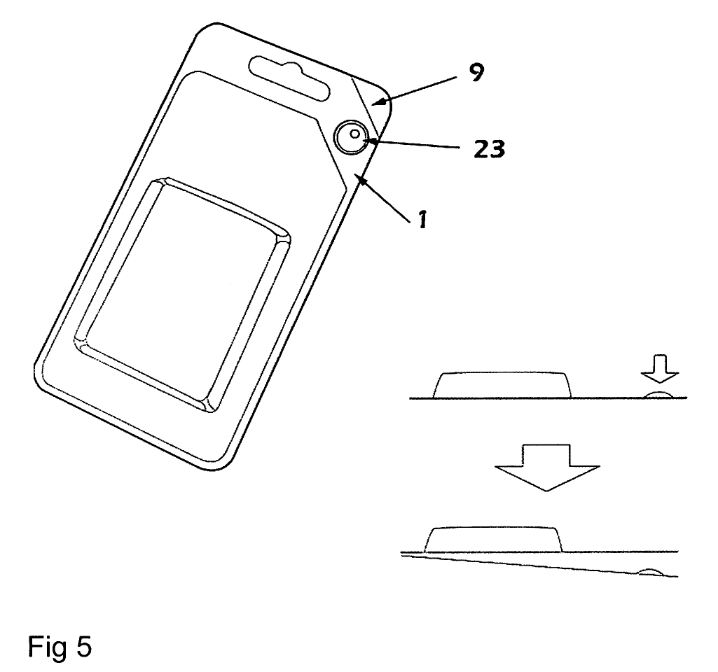

FIGS. 4 and 5 shows different ways of facilitating the separation of the walls after the breaking or weakening of the bonds in the electrically weakable adhesive.

FIG. 4 shows an embodiment of the inventive package, comprising a basic structure 9 and a pair of flaps 20, 21, located adjacent to the basic structure. Preferably, a first flap 20, is located on the first wall 1 and a second flap 21 is located on the second wall 2 so that the flaps partly overlaps. In order to prevent the user to falsely break up the package, the flaps are made small and weak. This makes it difficult for the user to get a grip of the flaps when the basic structure is sealed. When the bonds in the electrically weakable adhesive of the basic structure are weakened or broken, the user can get a grip on the flaps and the opening of the package is facilitated.

FIG. 5 shows another embodiment of the inventive package, comprising a basic structure 9, and a small, second, blister 23 in the second wall 2, which blister 23 is located close or adjacent to the basic structure 9. The first wall 1 comprises an opening or a hole opposite to the blister 23 of the second wall 2 such that the blister 23 extends through the whole. After the breaking or weakening of the bonds in the electrically weakable adhesive, the user presses the second blister, whereby the conductive surfaces are separated and the user can get a grip on one of the edges.

In another embodiment of the inventive package the package comprises a small, second, blister in one of the walls 1, which blister is located adjacent or close to the basic structure, but there is no opening or hole in the opposite wall. After breaking or weakening of the bonds in the electrically weakable adhesive, the user presses the small blister 23 downwards, which causes area around the blister to flex upwards whereby the conductive surfaces are separated and the user can get a grip on one of the edges.

In yet another embodiment, both of the walls comprise small blisters located close or adjacent to the basic structure extruded in the same direction such that a first blister in the first wall enclose a second blister in the second wall. After the weakening or breaking of the bonds in the electrically weakable adhesive, the user presses the blister, whereby the conductive surfaces of the basic structure is separated.

In yet another embodiment, the separation is facilitated by a tension in the structure. For example, an elastic material, such as rubber, can be used as an elastic material to form an elastic biasing force. The elastic material can be pressed together when curing or sealing the structure. The basic structure comprising the conductors and the electrically weakable adhesive can further comprise an elastic material. Alternatively the elastic material can be located on one or both of the walls adjacent to the basic structure. The elastic biasing can also be formed by the flexible material of one or both of the walls. This can for example be achieved by forming two blisters that are pressed together when the package is sealed. Preferably, a first small blister is formed on the first wall adjacent to the basic structure, and a second small blister is formed on the second wall corresponding to the first small blister.

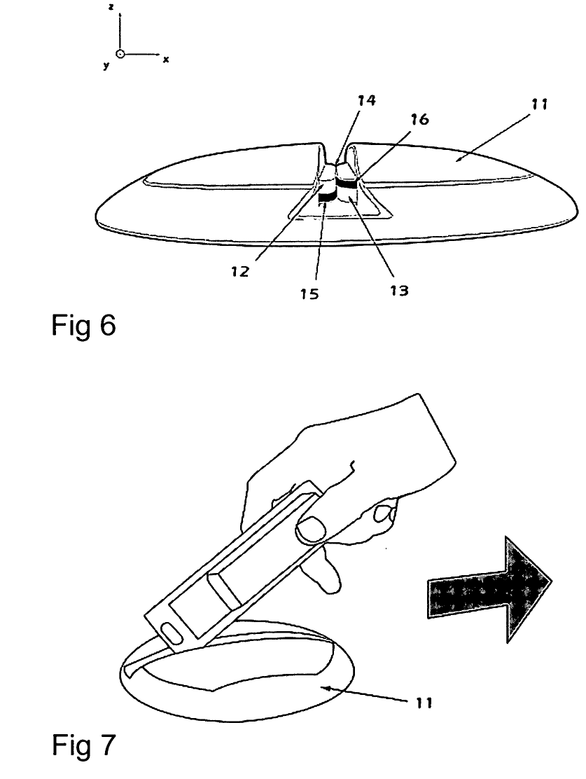

FIGS. 6 and 7 shows an example of an apparatus for supplying voltage to the conductive surfaces 5, 6 of the basic structure 9. The apparatus comprises a main body 11 and two flanges 12, 13 arranged spring-loaded adjacent to each other in a first direction(direction x) forming a swipe slot 14. The flanges 12, 13 comprise a pair of conductors 15, 16, adapted to be connected to a power supply. The user swipes the part of the package, which part is provided with the basic structure, through the slot 14 whereby current flows through the electrically weakable adhesive. The swiping movement improves the contact between the conductive surfaces of the basic structure and the conductors of the flanges, thus improving the voltage supply to the conductive surfaces. Furthermore the friction between the conductors and the flanges scratches off potential impurities, such as potential oxide layers on the conductors, which improves the contact even further.

In the embodiment shown in FIGS. 6 and 7, the apparatus further comprises at least one battery connected to the conductors 15, 16. In this embodiment the battery is arranged inside the main body 11. In an alternative embodiment to the one shown in FIGS. 6 and 7, the apparatus can be connected to an external voltage supply. The apparatus can for example form an integrated part of the cash register system, whereby no extra voltage supply is needed.

In a preferred embodiment of the invention, the voltage supplying apparatus further comprises at least one bar code reader. In this way the sales clerk only has to swipe the package once. In another embodiment, the apparatus can further comprise at least one card reader. This reduces the number of components needed at the cash register system. The apparatus can comprise a bar code reader as well as a card reader. The bar code reader and/or card reader can, e.g., be also located on the flanges 12, 13.

Preferably, the flanges 12, 13 forming the slot 14 are spring-loaded assuring contact between the conducting surfaces 5, 6 of the basic structure and the conductors 12, 13 regardless of the thickness of the conducting surfaces or the package.

As shown in FIG. 6, the flanges 12, 13, can be arranged adjacent to each other in a first direction (direction x). Alternatively the flanges, 12, 13, can be separated by a distance in the first direction, defining the width of the slot.

In one preferred embodiment, the conductors 15, 16 are arranged at a distance from each other in at least one direction. Preferably, the conductors 15, 16 are arranged at a distance from each other in a direction (direction z) of a normal to the first direction, i.e. in a direction perpendicular to the extension of the slot (i.e. perpendicular to the swiping movement), and also perpendicular to the width of the slot. This assures that direct contact between the conductors 15, 16 are avoided and thus prevents shortcircuiting.

In one preferred embodiment of the invention, the first conductor 15 is located at the upper part of the first flange facing the second flange and the second conductor 16 is located at the lower part of the second flange facing the first flange. The first and the conductors are located on different parts of the flanges such that direct contact of the conductors is avoided.

1. Package comprising;
two spaced apart first and second walls formed and joined to each other to define a cavity between them,
said walls having peripheral edges and being sealed together at a peripheral joint essentially along the edges
wherein a portion of said peripheral joint comprises at least two conductive surfaces and an electrically weakable adhesive.

2. Package according to claim 1,
wherein the walls comprise at least one conductive polymer.

3. Package according to claim 1, wherein the at least two conductive surfaces in a direction from the cavity to the peripheral joint at least partly extend past the first and second walls.

4. Package according to claim 1,
wherein a first conductive surface is located on the first wall and a second conductive surface is located on the second wall, wherein the electrically weakable adhesive is bridging the distance between the first and the second conductive surface.

5. Package according to claims 1,
further comprising at least one flap, located adjacent to the conductive surfaces.

6. Package according to claim 1,
further comprising a second blister adjacent to the conductive surfaces.

7. Package according to claim 1,
further comprising an elastic material tensioning the first and second wall towards opening of the package.

8. Package according to claim 7,
wherein the elastic material is located on at least one of the walls, adjacent to the conductive surfaces.

9. Package according to claim 8,
wherein the elastic material is located on at least one of the conductive surfaces.

10. An apparatus for supplying electrical power to the conductive surfaces of the package described in claim 1 comprising;
a first and a second flange opposing each other and thereby forming a swipe slot, wherein said flanges comprises at least two conductors
and a voltage supply adapted to apply a voltage between said conductors.

11. An apparatus according to claim 10 wherein said flanges are spring-loaded towards each other.

12. An apparatus according to claim 11, wherein said flanges are arranged adjacent to each other in a first direction (direction X) in the direction of the width of the slot.

13. An apparatus according to claim 12,
wherein said conductors are separated in a direction (direction z) perpendicular to said first direction and preferably also perpendicular to the direction of the swiping movement.

14. An apparatus according to claim 10, wherein said conductors are separated in a first direction (direction x) defining the width of the slot.

15. An apparatus according to claim 14,
wherein said conductors are separated in a second direction (direction z) perpendicular to said first direction and preferably also perpendicular to the direction of the swiping movement.

16. An apparatus according to claim 10 further comprising a bar code reader.

17. An apparatus according to claim 10 further comprising a card reader.

18. A method comprising;
providing two spaced apart first and second walls forming a cavity between them, said walls having peripheral edges, sealing said walls together at a peripheral joint essentially along the edges,
providing a portion of said peripheral joint with at least two conductive surfaces and an electrically weakable adhesive.

19. A method comprising;
providing a blister package with at least two conductive surfaces and an electrically weakable adhesive and swiping the part of said blister pack comprising said two conductive surfaces through a voltage supplying apparatus
